(19) United States
(12) Patent Application Publication
(10) Pub. No.: US 2010/0155931 A1
(43) Pub. Date: Jun. 24, 2010

(54) Embedded Through Silicon Stack 3-D Die In A Package Substrate

(75) Inventors: Urmi Ray, Ramona, CA (US); Fifin Sweeney, San Diego, CA (US); Kenneth Kaskoun, La Jolla, CA (US); Shiquin Gu, San Diego, CA (US); Thomas R. Toms, Dripping Springs, TX (US)

Correspondence Address: QUALCOMM INCORPORATED, 5775 MOREHOUSE DR., SAN DIEGO, CA, 92121, US

(73) Assignee: QUALCOMM INCORPORATED, San Diego, CA (US)

(21) Appl. No.: 12/340,862

(22) Filed: Dec. 22, 2008

(51) Int. Cl. H01L 23/538; H01L 21/50

(52) U.S. Cl. 257/698; 438/127; 257/E23.174; 257/E21.499

(57) ABSTRACT

An integrated circuit package has a die or die stack with through silicon vias embedded in a package substrate. A method of producing an integrated circuit package embeds at least one die with a through silicon via in a package substrate. The package substrate provides a protective cover for the die or die stack.

### TECHNICAL FIELD

The present disclosure is in the field of integrated circuits. More specifically, the present disclosure involves embedded and through silicon stack integrated circuit packaging.

### BACKGROUND

Integrated circuits are the cornerstone of most modern day electronic devices. Integrated circuits are a microscopic array of electronic circuits and components made together or integrated-hence the name. Initially, integrated circuits held only a few devices, probably as many as ten diodes, transistors, resistors and capacitors that allow the integrated circuit to fabricate one or more logic gates. Today, very-large-scale integration (VLSI) has created integrated circuits with millions of gates and hundreds of millions of individual transistors. Integrated circuits are found in devices such as computers and cellular phones. Over the years, scientists have significantly reduced the size of integrated circuits. In turn, these smaller integrated circuits bring about smaller electronic devices. The decrease in size of integrated circuits over the years, has been so dramatic that to decrease their size even further is difficult.

Usually, integrated circuits are produced on a single wafer of electronic grade silicon and then cut into pieces. Each piece represents a copy of the circuit and is called a die. An integrated circuit package is a die mounted within a protective housing where pads of the die interconnect to external pins, (e.g., dual in-line packages) or pads (e.g., ball grid array packages) of the housing using bond wires or flip chip bumps. Typically, an integrated circuit package includes one die. Integrated circuit packages that contain more than one die conventionally have dies stacked adjacent to each other.

A recent method of producing dies involves stacking dies that have small openings through them wherein these small openings include conductive material therein to provide an electrical path through the dies. These openings with conductive material are known as through silicon vias (TSVs). Integrated circuits that have stacked dies interconnected with through silicon vias are known as through silicon stacks or “TSS.”

Separately, specialists in the package substrate field have recently developed technology that embeds dies in package substrates. This is known as embedded die in a package substrate or “EDS.” In the methods of production described above, the packages are either bulky and/or the degree of interconnection amongst the dies and other components is limited. For example, in the EDS method, interconnections to a die can only be made on one face of the die.

In the TSS method, the dies are placed on top of the package substrate. This limits the effectiveness of the TSS method when manufacturers must incorporate passive devices such as inductors, antennas, diodes, transistors, resistors and capacitors in the integrated circuit package because of size and cost.

Wire bond or solder electrically couples the layers of TSS devices. The wire bond or solder connections are problematic because they require the application of heat and/or pressure to metals forming the bond or solder. Thus, wire bond or solder installation is difficult because the application of heat or pressure, if not done properly, can damage layers of the TSS device.

Additionally, because the dies in the TSS method are on top of the package substrate these TSS integrated circuit packages are large. The larger the packages are, the longer the length of the electrical connections between devices. The longer the connections between devices, the higher the level of power required to pass electricity through these connections.

In sum, issues of package size and effectiveness of making electrical connections to devices in integrated circuit packages remain despite the significant developments in the various fields over the years.

### BRIEF SUMMARY

The present disclosure solves the problems of large package size and ineffective or insufficient die connection sites by providing electrical paths through a die (by through silicon vias in the die) and, simultaneously, to the die (by a conductive layer in a package substrate). Further, the package substrate forms a protective cover over the die. One embodiment of the disclosure involves at least partially embedding at least one die having through silicon vias, in a package substrate. Another embodiment involves at least partially embedding a die stack with through silicon vias in a package substrate. Embedding a die or die stack in a package substrate, instead of placing the die or die stack on top of the package substrate as done in some integrated circuit packages, allows the efficient use of space in the package while utilizing the package substrate for providing electrical paths to couple the die to other devices. Moreover, the through silicon vias of the die or die stack that are embedded in the package substrate allow coupling to both faces of the die and thus avoid routing electrical paths around the die.

Embedding the die in the package substrate eliminates the need to interconnect the die on top of the package substrate by solder. This in turn lowers manufacturing costs. Further, embedding a die or die stack with through silicon vias in the package substrate eliminates cross-talk amongst devices in the integrated circuit package. The reduction of cross-talk is achieved by several factors. First the interconnect node physical size is reduced, lowering interconnect capacitance and thus reducing the size and power required to switch the nodes. Accordingly, signal integrity is improved. Second, the physically smaller loops lower both loop and mutual inductance.

In one embodiment, an integrated circuit includes a die having through silicon vias; and a package substrate in which the die is at least partially embedded. At least one of the through silicon vias is electrically coupled to electrical paths in the substrate.

In another embodiment, an integrated circuit package includes stacked dies, at least one of the stacked dies having at least one through silicon via. The integrated circuit also includes a package substrate in which the stacked dies are at least partially embedded.

In yet another embodiment, a method producing an integrated circuit is disclosed. The method includes at least partially embedding at least one die having at least one through silicon via in a package substrate.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiments disclosed may be readily utilized as a basis for modifying or designing other structures for carrying out the same purposes of the present disclosure. It should also be realized by those skilled in the art that such equivalent constructions do not depart from the spirit and scope of the disclosure as set forth in the appended claims. The novel features which are believed to be characteristic of the disclosure, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following descriptions taken in conjunction with the accompanying drawing.

FIG. 1 represents a conventional stacked integrated circuit package.

FIG. 2 represents an embedded die package substrate.

FIG. 3 represents a through silicon stack.

FIGS. 4A-4C represent embodiments of the current disclosure.

FIGS. 5A and 5B show a method for carrying out one embodiment of the current disclosure.

FIG. 6 represent a conventional integrated circuit package.

FIG. 7 represents an embodiment of the current disclosure.

### DETAILED DESCRIPTION

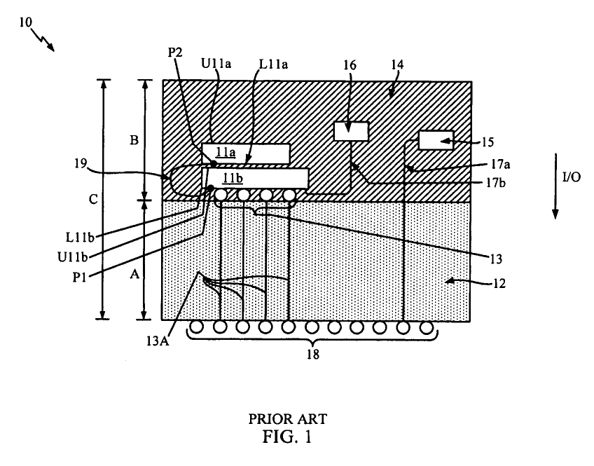

FIG. 1 illustrates a conventional stacked integrated circuit package represented here as integrated circuit package 10. Integrated circuit package 10 includes dies 11a and 11b stacked on top of a package substrate 12. In this application, a package substrate is a material that provides base mechanical support to the devices of an integrated circuit. In one embodiment, the package substrate 12 is a printed circuit board of an organic material. Exemplary materials include GETEK, flame retardant 4 (FR-4), flame retardant 5 (FR-5), and materials available from Rogers Corporation.

Conventionally, dies have only one electrically active face. Consequently, electrical connections are usually made only to that active face. Because electrical connections are only made to the active face, the input and output (I/O) of the dies and integrated circuit package are in one direction only. In the current example, faces L11b and L11a are active while U11a and U11b are not. Therefore, wire bond 19 couples point p1 on face L11b by a route around 11b to point p2 on face L11a. Significantly, wire bond 19 is not the shortest possible distance coupling points p1 and p2.

Solder balls 13 attach die 11b to package substrate 12. Conductors 13A, which run through package substrate 12, electrically couple die 11b to external solder balls 18. External solder balls 18 serve to couple, electrically and physically, integrated circuit package 10 to any external device or circuitry such as a main board of an electronic device (not shown). Over mold 14 covers and protects dies 11a and 11b. Apart from dies, integrated circuit packages sometimes include passive devices such as antenna 15 and inductor 16. Wire bond 17a couples antenna 15 to a device (not shown) external to integrated circuit package 10. Wire bond 17b couples inductor 16 to die 11b. Other passive devices include, but are not limited to a diode, a transistor, a resistor and a capacitor.

As discussed above, the size of an integrated circuit package is important. It should be noted, therefore, that the total height C of integrated circuit package 10 is the sum of the package substrate height A and the height B of over mold 14.

The types of connections between devices in an integrated circuit package are important. Wire bond 19 requires high loads to pass electrical signals through them, in part, because the wire bonds are long and the longer the wire bonds the higher the load required to route electrical signals from one die's active face to another.

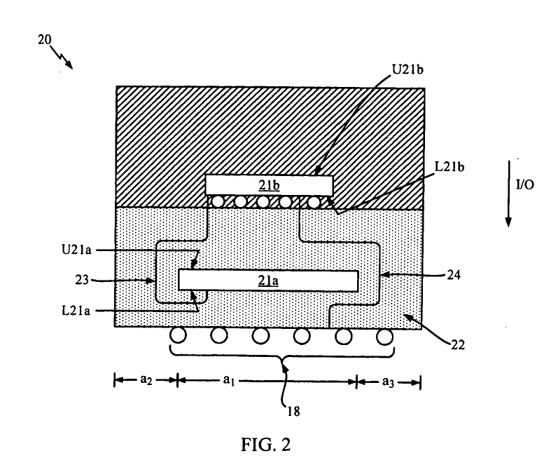

FIG. 2 depicts a recent development in package substrate technology-an embedded die in an integrated circuit package substrate. The embedded die in a package substrate circuit is still in the development stage and may not yet be commercially available or widely known. Here, die 21a is embedded in package substrate 22. As mentioned above, however, connections to dies are made only on the die's active face. In integrated circuit package 20, connections to die 21a and die 21b are made on faces L21a and L21b respectively. Connections cannot be made to die 21a and die 21b through face U21a. It should be noted that like integrated circuit package 10, the I/O of integrated circuit package 20 is in one direction only. Because a single active face for each die limits the sites to which another device couples to dies 21a and 21b, electrical path 23 couples active faces L21a and L21b. Electrical path 23, however, is long because it must be routed through area a2 and avoid, as much as possible, area a1 in which die 21a is located. Thus, the wider die 21a is, the larger the electrical path route (such as between points on L21a and L21b) needs to be. Similarly, if a connection between 21b and an external device (not shown) is needed, the electrical path must be routed to avoid area a1. Consequently, path 24, which couples 21b to an external device, is long.

Because die 21a occupies so much space, it limits the ways in which devices may be coupled. For example, it is difficult for die 21b to have access to solder balls 18 because die 21a is a barrier between die 21b and solder balls 18.

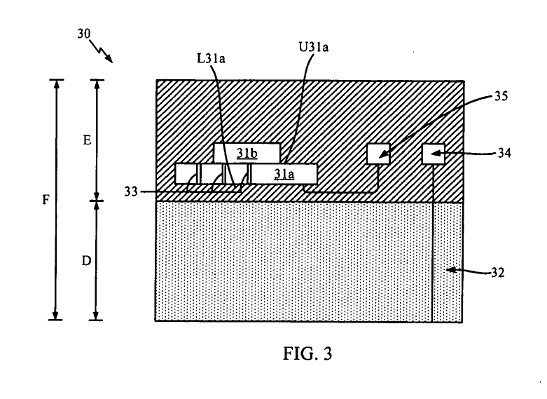

FIG. 3 depicts a recent development—a through silicon stack integrated circuit 30. The through silicon stack integrated circuit is still in the development stage and may not yet be commercially available. The through silicon stack method stacks die 31b on

The height D of package substrate 32 is substantially the same as height A of package substrate 12 (FIG. 1) because dies 31a and 31b are on top of package substrate 32. Die 31a and die 31b, being on top of package substrate 32, need to be protected by an over mold of a height similar to that found in traditional integrated circuit packages. That is, height E is substantially the same as height B (FIG. 1).

Moreover, because devices such as antenna 34 and inductor 35 are in the over mold they have to be coupled to by wire bonds or bumps. The length of the interconnects and consequently the load to pass electricity through them is unsuitable for high speed and high performance applications.

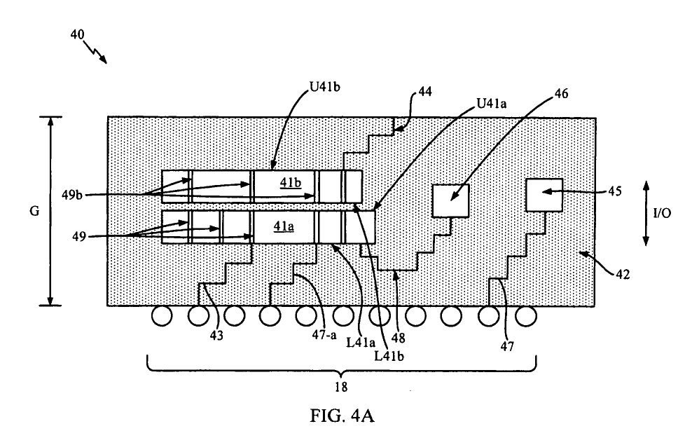

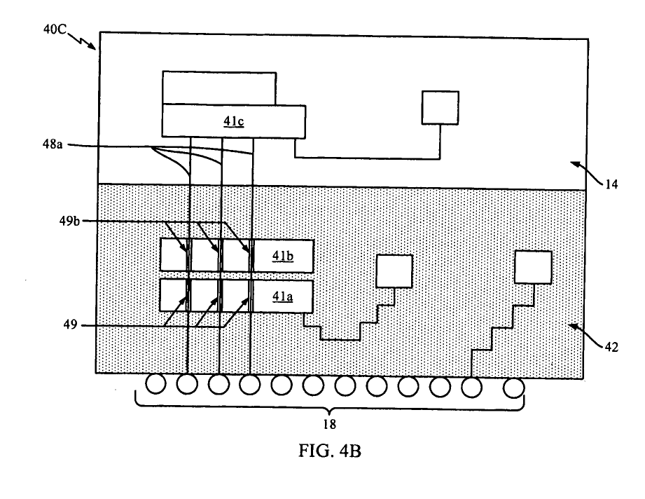

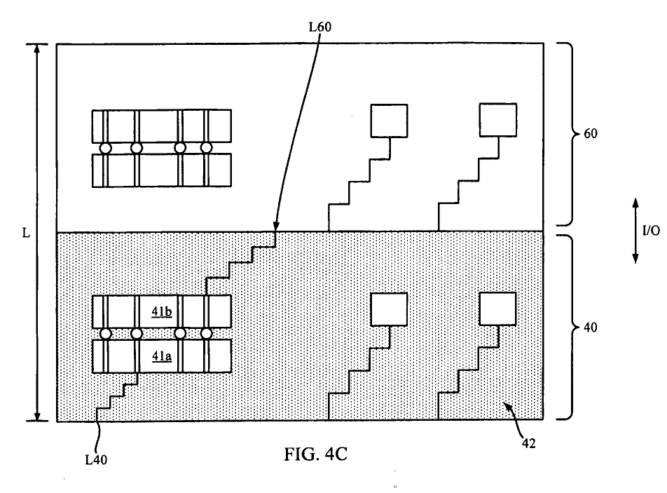

FIG. 4A depicts one embodiment of the disclosure. Integrated circuit package 40 includes die 41a embedded in package substrate 42. Die 41a has through silicon vias 49 that allow electrical paths through die 41a. Providing through silicon vias 49 in die 41a while die 41a is embedded in package substrate 42 provides more efficient connections between devices and greater flexibility in making these connections. Through silicon vias 49 allow electrical connections on both faces of die 41a. In other words, a connection to the active face is possible on the inactive face. For example, connections to active face L41a may be made at inactive face U41a, enabling die 41b to access the active face using the through silicon vias 49.

Additionally, through silicon vias 49 gives die 41b short access not only to both faces of die 41a but also to solder balls 18 through path 47a. Without through silicon vias 49, the path from die 41b to solder balls 18 would have to be around die 41a which is necessarily a longer path, similar to paths 23 and 24 in FIG. 2.

If desired, at least one more die may be placed on top of substrate 42 (as shown in FIG. 4B). If this is done, through silicon vias 49b allows coupling from the die on top of substrate 42 to any of the faces of die 41b and, in conjunction with through silicon vias 49, any face of die 41a. In addition, the die(s) on top of the substrate 42 can access solder balls 18 using through silicon vias 49 and 49b. As a result of coupling to both faces of a die, input and output (I/O) signals can be provided in two directions in the integrated circuit package: towards contacts on the bottom of the package and toward contacts on the top of the package. Thus, in an integrated circuit package with multiple embedded dies, each die may be easily coupled to other dies or other devices, in embodiments of the disclosure. In sum, placing through silicon vias in dies that are embedded in a package substrate reduces connection paths and significantly increases the possible sites on devices for these connections.

As depicted in FIG. 4A, dies 41a and 41b represent a die stack embedded in package substrate 42. In some embodiments, however, only one die may be embedded in the package substrate. In other embodiments, more than one die is embedded in the package substrate but not in a die stack, for example the dies are side-by-side or laterally disposed.

Package substrate 42 also facilitates package substrate connections, for example, paths 43 and 44 to faces L41a and U41b respectively. In addition, substrate interconnect technology may also provide connections for inductor 45 and antenna 46. Paths 47 and 48 eliminate the need to use wire bonds when coupling inductor 45 and antenna 46 to other devices. As described above, coupling to devices such as inductors and antennas is difficult. This difficulty is avoided in integrated circuit package 40 where embedded device substrate technology is used. In this case (not shown), the passive elements 45, 46 are placed on top of the package substrate 42

Furthermore, embedding dies 41a and 41b in package substrate 42 uses package substrate 42 as a protective cover for dies 41a and 41b and thereby eliminates the need for an over mold. Thus, integrated circuit package 40's height G is less than height C of today's integrated circuit package 10 (FIG. 1). That is, the height of the over mold such as height B of over mold 14 is eliminated (FIG. 1).

Another advantage of the present disclosure is that a tier of a stacked IC device need not be thicker to enable coupling with a package substrate. Conventionally, the bottom tier of a stacked IC device is manufactured as a thicker tier to withstand the forces necessary to electrically bond the stacked IC device to the package substrate. The present disclosure, however, encapsulates the stacked IC device in the package substrate reducing (or possibly eliminating) forces needed to electrically bond the stacked IC device to the package substrate.

FIG. 4B shows an embodiment in which, instead of eliminating over mold 14, over mold 14 is included and allowed to contain more devices, thereby increasing the capacity of the integrated circuit package. That is, integrated circuit package 40C could be the same size as today's integrated circuit package such as package 10, but contains many more devices than can be accommodated in package 10. It should be noted that through silicon vias 49 and 49b allow connections 48a to run from die 41c through dies 41a and 41b to solder balls 18.

In sum, embedding dies, which have through silicon vias, into a package substrate, according to embodiments, simultaneously creates many benefits in an integrated circuit package. Embedding dies, according to embodiments, reduces integrated circuit package size and/or increases the density or capacity of the integrated circuit package to accommodate devices. Further, it increases the flexibility to couple to devices inside and outside of the integrated circuit and thus allows circuit configurations that were not previously possible. Additionally, embedding the dies in the package substrate avoids long electrical paths and thereby reduces power consumption. Moreover, embedding the dies improves the quality of connectors for passive devices such as inductors and antennas. It should be noted that in some embodiments of the disclosure a die may be partially embedded, i.e., not completely covered with the package substrate.

FIG. 4C depicts another embodiment of the disclosure with a die stack including die 41a and die 41b embedded in package substrate 42. This embodiment also provides the possibility of a package on package layout because connections can be made to either face of the dies. Here, package 60 has been placed on top of package 40. A direct coupling between the lower surface L40 of package 40 and the lower surface L60 of package 60 is made with short wires. More packages may be added above package 60 and below package 40 as desired. It should be noted that because embedding the dies in the package substrates reduces the overall package size, it is possible in embodiments of this disclosure to include multiple packages in the space that would, in existing technology, accommodate one die.

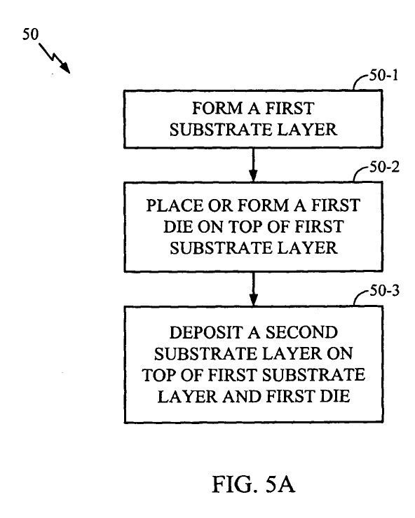

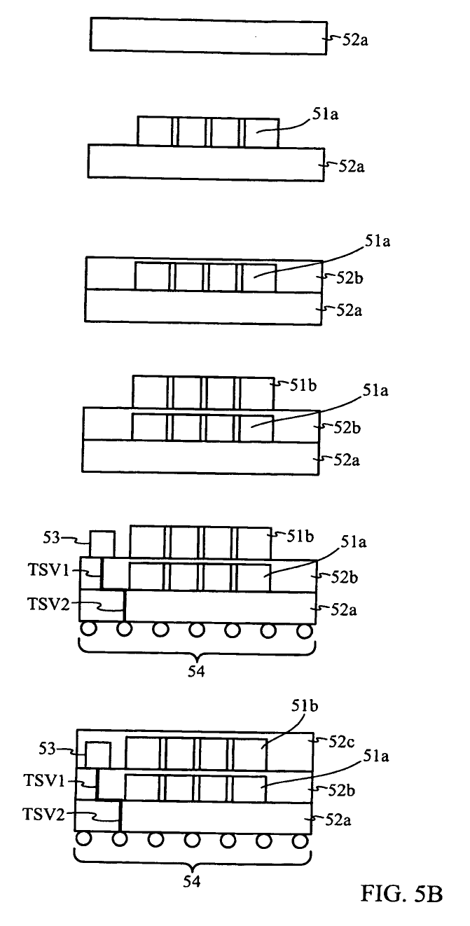

FIG. 5A shows process 50 for producing a die stack embedded in a package substrate. FIG. 5B shows how process 50 arranges the components, as well as additional components not included in process 50. Block 50-1 forms a package substrate layer 52a. Block 50-2 then stacks die 51a, a die having through silicon vias in it, on top of package substrate layer 52a. Block 50-3 deposits a second package substrate layer 52b on top of layer 52a and die 51a. Package substrate layer 52b completely embeds die 51 a in package substrate 52a, 52b and provides a way to couple die 51a to other components, for example die 51b on top of package substrate 52a, 52b. This coupling is created by substrate build up layer technology which provides metallization in package substrate layers 52a, 52b below and on top of die 51b. Thus, metallization (not shown) within package substrate 52a, 52b couples die 51a to die 51b and also couples die 51a to the ball grid array 54.

In one embodiment, substrate build up layer technology can bond die 51a with another stacked die (not shown) that is part of a TSS device (not shown). In this embodiment, the substrate lamination process avoids the need to separately bond dies of the stack as is conventionally done with stacked integrated circuit devices. For example, the force and heat from the substrate lamination could bond the dies of the stacked IC device. In one embodiment, indium can facilitate bonding of the dies.

Although FIGS. 5A and 5B only disclose two layers of a substrate, in another embodiment a core substrate layer is provided on top of lower substrate layer 52a. The core layer includes a space in which die 51a sits. After the die 51a (or die stack) is placed within the core layer, the top substrate layer 52b is added.

Passive devices, such as antenna 53 may be placed in particular layers as the package substrate is built up from 52a. In the current example, a passive device such as antenna 53, is placed above layer 52b. The antenna 53 and die 51-b are embedded with package substrate layer 52c. Substrate layer 52c also provides sealing and protection to dies 51a, 51b and antenna 53.

It should also be noted that the electrical paths are fabricated in the substrate layers by metallization within the layers. Further, substrate vias from one package substrate layer to another can be provided to electrically couple across layers or from one layer to another layer. For example, substrate through silicon vias TSV1 and TSV2 allow antenna 53 to couple to any external or internal device or circuit such as solder balls 54 which in turn may couple to an external device (not shown).

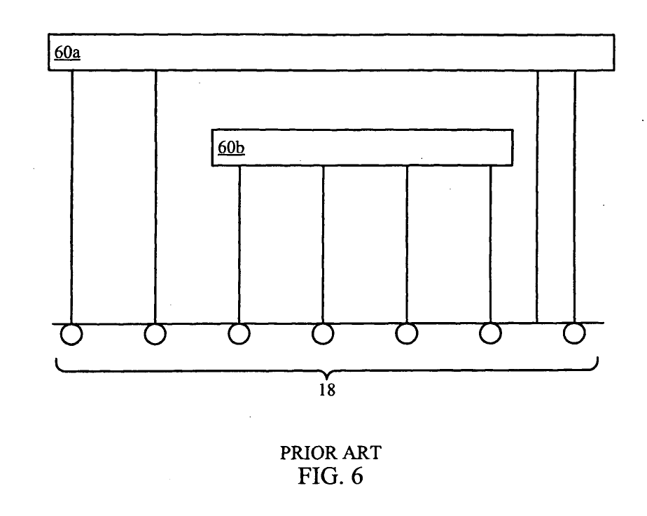

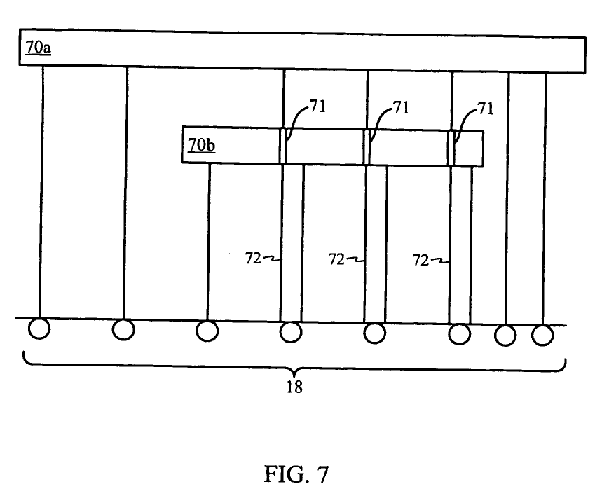

Embodiments of the current disclosure provide more flexibility in how dies are stacked in an integrated circuit. A comparison between FIGS. 6 and 7 illustrates the flexibility of embodiments of the current disclosure compared with a conventional configuration. FIG. 6 represents prior art. To illustrate a benefit of embodiments of the disclosure, it is assumed that both the prior art in FIG. 6 and the embodiment of the disclosure in FIG. 7 must have vertical connections between dies of the integrated circuit and solder balls of the integrated circuit package. With this constraint, it can be seen that die 60b limits the electrical connections of die 60a to solder balls 18 to the outer edges of die 60a because die 60b prevents any vertical connections between the inner portions of die 60a and solder balls 18.

In contrast, in FIG. 7, die 70b has through silicon vias 71 that allow electrical connections 72 between die 70a and solder balls 18 at the inner portions of die 70a. Thus, in this embodiment of the disclosure there is much more flexibility in coupling the die 70a and solder balls 72 compared with die 60a in FIG. 6.

Although the terminology “through silicon via” includes the word silicon, it is noted that through silicon vias are not necessarily constructed in silicon. Rather, the material can be any device substrate material.

Although the present disclosure and its advantages have been described in detail, it should be understood that various changes, substitutions and alterations can be made herein without departing from the spirit and scope of the disclosure as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. An integrated circuit comprising:
a die having through silicon vias; and
a package substrate in which the die is at least partially embedded, wherein at least one of the through silicon vias is electrically coupled to electrical paths in the substrate.

2. The integrated circuit of claim 1 further comprising:
a passive device embedded in the package substrate.

3. The integrated circuit of claim 1, further comprising a passive device on the package substrate.

4. The integrated circuit of claim 2 wherein the passive device is at least one of an inductor, an antenna, a diode, a transistor, a resistor and a capacitor.

5. The integrated circuit of claim 1 wherein the package substrate provides a protective cover for the die.

6. The integrated circuit of claim 1 further comprising:
a second die in the substrate, wherein at least one of the through silicon vias in the first die provides an electrical path to the second die.

7. The integrated circuit of claim 6 wherein at least one of the electrical paths to the second die and at least one of the electrical paths in the substrate couple the second die to a ball grid array.

8. The integrated circuit of claim 6 further comprising:
a third die, wherein at least one the electrical path to the second die couples the second die to the third die.

9. An integrated circuit package comprising:
a plurality of stacked dies, at least one of the stacked dies having at least one through silicon via; and
a package substrate in which the stacked dies are at least partially embedded.

10. The integrated circuit package of claim 9 further comprising:
a passive device embedded in the package substrate.

11. The integrated circuit package of claim 10 wherein the passive device is at least one of an inductor, an antenna, a diode, a transistor, a resistor and a capacitor.

12. The integrated circuit package of claim 9 wherein the package substrate provides a protective cover for the stacked dies.

13. A method of producing an integrated circuit, the method comprising:
at least partially embedding at least one die having at least one through silicon via in a package substrate.

14. The method of claim 13 wherein the embedding comprises building the substrate in layers.

15. The method of claim 14 wherein the die is embedded during the layer build up.

16. The method of claim 14 further comprising:
creating electrical paths between the layers.

17. The method of claim 14 further comprising:
creating electrical paths across the layers.

18. The method of claim 13 further comprising:
electrically coupling the at least one through silicon via to electrical paths in the substrate.

19. The method of claim 13 further comprising:
embedding a passive device in the substrate.

20. The method of claim 19 further comprising coupling the passive device to another device with a through silicon via.
